(19) United States
(12) Patent Application Publication
(10) Pub. No.: US 2010/0064972 A1
(43) Pub. Date: Mar. 18, 2010

(54) CVD FILM FORMING APPARATUS

(75) Inventors: Hideaki YAMASAKI, Nirasaki-shi (JP); Isao GUNJI, Nirasaki-shi (JP); Daisuke KUROIWA, Nirasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Minato-ku (JP)

(21) Appl. No.: 12/568,139

(22) Filed: Sep. 28, 2009

Related U.S. Application Data
(63) Continuation of application No. PCT/JP08/55450, filed on Mar. 24, 2008.

(30) Foreign Application Priority Data
Mar. 28, 2007 (JP) 2007-083870

(51) Int. Cl. C23C 16/458

(52) U.S. Cl. 118/724

(57) ABSTRACT

A CVD film forming apparatus for forming a predetermined film on a target substrate via CVD by reacting a film forming gas on a surface of the substrate while heating the substrate includes a processing chamber capable of being maintained at vacuum, and a stage for mounting thereon the substrate in the processing chamber, the stage having a diameter larger than that of the substrate. Further, the CVD film forming apparatus includes a heating device provided in the stage to heat the substrate, a gas supply unit for supplying the film forming gas into the processing chamber, a gas exhaust device for exhausting the processing chamber to vacuum, and a covering for covering a peripheral region of the stage that surrounds the substrate mounted on the stage to reduce thermal effects from the stage to a peripheral portion of the substrate.

This application is a Continuation Application of PCT International Application No. PCT/JP2008/055450 filed on Mar. 24, 2008, which designated the United States.

### FIELD OF THE INVENTION

The present invention relates to a CVD film forming apparatus for forming a film via CVD by heating a target substrate mounted on a stage in a processing chamber maintained at vacuum.

### BACKGROUND OF THE INVENTION

In a manufacturing process of semiconductor devices, a film formation process for forming a predetermined film on a semiconductor wafer (hereinafter, simply referred to as a “wafer”) serving as a target substrate is performed. Chemical vapor deposition (CVD) is widely used as the film formation process. When the film formation process is carried out via CVD, a wafer is mounted on a stage having a heater embedded therein in a processing chamber and is heated while supplying a predetermined processing gas to the processing chamber to form a film via chemical reaction on the wafer. In this case, a stage having a diameter larger than that of the wafer is used in order to uniformly heat the wafer (see, e.g., Japanese Patent Laid-open Publication H11-40518).

In the film formation process, the temperature of the stage is higher than that of the wafer and the surface temperature of the peripheral portion of the stage (i.e., an area in which the wafer is not mounted) is higher than the temperature of the wafer. Depending on gas types and film formation conditions, decomposition of a source gas is accelerated above the peripheral portion of the stage and the film is thickly formed on a peripheral portion of the wafer adjacent thereto.

### SUMMARY OF THE INVENTION

In view of the above, the present invention provides a CVD film forming apparatus for forming a predetermined film without increasing a film thickness at a peripheral portion of a target substrate.

In accordance with a first aspect of the present invention, there is provided a CVD film forming apparatus for forming a predetermined film on a target substrate via CVD by reacting a film forming gas on a surface of the substrate while heating the substrate, the apparatus comprising: a processing chamber capable of being maintained at vacuum; a stage for mounting thereon the substrate in the processing chamber, the stage having a diameter larger than that of the substrate; a heating device provided in the stage to heat the substrate; a gas supply unit for supplying the film forming gas into the processing chamber; a gas exhaust device for exhausting the processing chamber to vacuum; and a covering for covering a peripheral region of the stage that surrounds the substrate mounted on the stage to reduce thermal effects from the stage to a peripheral portion of the substrate.

In the first aspect, a surface of the covering in contact with the stage may have an emissivity lower than an emissivity of the stage. Further, the stage may be made of ceramic, and the surface of the covering in contact with the stage may have an emissivity of 0.38 or less. Further, a material and shape of the covering may be determined such that a temperature difference between the covering and the substrate is adjusted to 90° C. or less when the substrate is heated by the heating device. Further, at least a part of the covering including the surface in contact with the stage may be made of tungsten, and the covering may be made of only tungsten.

In accordance with a second aspect of the present invention, there is provided a CVD film forming apparatus for forming a predetermined film on a target substrate via CVD by reacting a film forming gas on a surface of the substrate while heating the substrate, the apparatus comprising: a stage for mounting thereon the substrate in a processing chamber, the stage having a diameter larger than that of the substrate; a heating device provided in the stage to heat the substrate; a gas supply unit for supplying the film forming gas into the processing chamber; a gas exhaust device for exhausting the processing chamber to vacuum; and a covering for covering a peripheral region of the stage that surrounds the substrate mounted on the stage, the covering including a basic member and a low emissivity film formed on at least a backside surface of the basic member.

In the second aspect, the stage may be made of ceramic and the low emissivity film of the covering may have an emissivity of 0.38 or less. Further, the basic member may be made of silicon and the low emissivity film may be made of tungsten. Further, the low emissivity film may have a thickness of 100 nm or more. Further, a material and shape of the basic member and the low emissivity film of the covering may be determined such that a temperature difference between the covering and the substrate is adjusted to 90° C. or less when the substrate is heated by the heating device.

In the CVD film forming apparatus of the first and second aspects, the covering may have a ring shape to surround the peripheral portion of the substrate. Further, the covering may have a thickness of 1 mm to 3 mm. Further, the gas supply unit may supply the film forming gas by using a metal material which is decomposed at a temperature of 150° C. or less.

In accordance with the aspects of the present invention, a covering which covers the peripheral region of the stage is provided to reduce thermal effects from the stage to the peripheral portion of the substrate. It is possible to prevent an increase in temperature at the peripheral region of the stage that surrounds the substrate mounted on the stage. Further, it is possible to form a predetermined film without increasing a film thickness at the peripheral portion of the substrate.

Further, the covering includes a basic member and a low emissivity film formed on the surface of the basic member. Accordingly, the covering can efficiently reduce thermal effects from the stage to the peripheral portion of the target substrate due to the low emissivity film present at an interface portion between the covering and the stage.

Further, as used herein, “a covering for reducing thermal effects from a stage to a peripheral portion of a target substrate” refers to a member which prevents a temperature increase at the peripheral region of the stage (i.e., a region in which the target substrate is absent) to make the surface temperature of the peripheral region of the stage close to the temperature of the target substrate.

### BRIEF DESCRIPTION OF THE DRAWINGS

The other objects and features of the present invention will become apparent from the following description of embodiments, given in conjunction with the accompanying drawings, in which:

FIG. 1 is a cross sectional view illustrating a CVD film forming apparatus in accordance with an embodiment of the present invention;

FIG. 2 is an enlarged cross sectional view illustrating the edge covering provided in the CVD film forming apparatus in accordance with the embodiment of the present invention;

FIG. 3 is a schematic view illustrating the temperatures of a stage and a wafer when an edge covering is not provided;

FIG. 4 is a schematic view illustrating a model to simulate a difference in effects depending on the structure of the edge covering;

FIG. 5 illustrates a relationship between a W film thickness in the edge covering and emissivity of the backside surface of the edge covering;

FIG. 6 illustrates in-plane distribution of sheet resistance, in cases of using an edge covering having a W film, using an edge covering having no W film, and using no edge covering;

FIG. 7 illustrates a relationship between the temperature of the edge covering and uniformity of sheet resistance;

FIG. 8 shows a relationship between emissivity of the backside surface of the edge covering and the temperature of the edge covering; and

FIG. 9 is a graph showing in-plane distribution of sheet resistance with variation of the thickness of the edge covering.

### DETAILED DESCRIPTION OF THE EMBODIMENTS

Hereinafter, embodiments of the present invention will be described in detail.

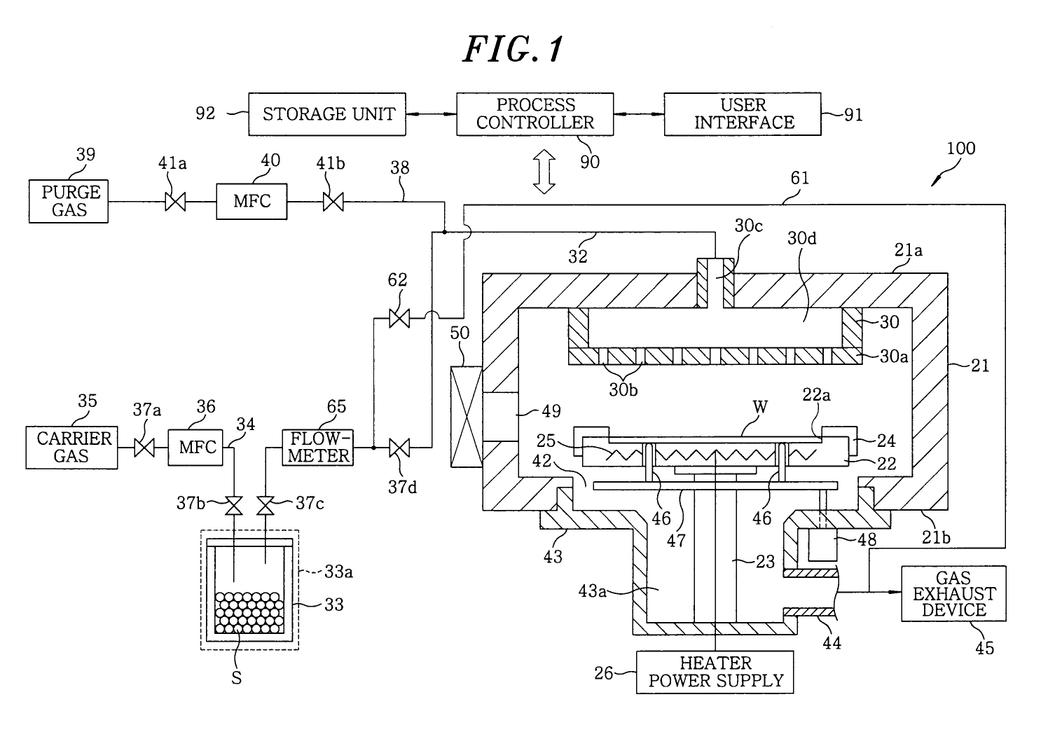

FIG. 1 is a cross sectional view showing a schematic configuration of a CVD film forming apparatus for forming a tungsten (W) film in accordance with an embodiment of the present invention.

The film forming apparatus 100 includes a processing chamber 21 which is hermetically sealed and has an approximately cylindrical shape. A circular opening 42 is formed at a central portion of a bottom wall 21b of the processing chamber 21. A gas exhaust chamber 43 is provided at the bottom wall 21b to communicate with the opening 42 and protrude downward.

A stage 22 made of ceramic, e.g., AlN, is provided in the processing chamber 21 to horizontality mount thereon a wafer W serving as a target substrate. A resistance heater 25 is embedded in the stage 22, and power is supplied from a heater power supply 26 to the heater 25 to heat the stage 22, thereby heating the wafer W serving as a target substrate. That is, the stage 22 is configured as a stage heater. The stage 22 is set at a temperature suitable for film formation, e.g., about 675° C., when the wafer W is set to a temperature, e.g., 500° C. Further, the stage 22 is supported by a cylindrical support member 23 which extends upward from a central bottom portion of the gas exhaust chamber 43.

The stage 22 has a diameter larger than that of the wafer W and is provided, on its top surface, with a ring-shaped spot facing part 22a to accept a wafer W. An edge covering 24 is provided at an outside of the spot facing part 22a of the stage 22. That is, as described above, for example, when the temperature of the wafer W is set to 500° C., the stage 22 is about 675° C., and a peripheral region of the stage 22 that surrounds the wafer W mounted on the stage 22 has a temperature higher than the temperature of the wafer W. Accordingly, in order to reduce thermal effects from the stage 22 to a peripheral portion of the wafer W, the edge covering 24 is provided on the stage 22 to surround an outer portion of the wafer W. A more detailed explanation of the edge covering 24 will be given later.

Three supporting pins 46 (only two pins are shown) for supporting and elevating the wafer W are provided in the stage 22 to be protruded from the surface of the stage 22 and retracted into the surface of the stage 22. The wafer supporting pins 46 are fixed on a support plate 47. Further, the wafer supporting pins 46 are elevated via the support plate 47 by a driving unit 48 such as an air cylinder.

A shower head 30 is provided at a top wall 21a of the processing chamber 21. The shower head 30 includes a shower plate 30a having a plurality of gas discharge holes 30b to discharge gas toward the stage 22 arranged thereunder. A gas inlet port 30c is provided at an upper wall of the shower head 30 to introduce gas into the shower head 30. The gas inlet port 30c is connected to a line 32 for supplying a W(CO)₆ gas. Further, the shower head 30 includes a diffusion area 30d therein.

The other end of the line 32 is inserted into a film forming material container 33 containing a solid material S of W(CO)₆ as a film forming material. A heater 33a serving as a heating device is provided around the film forming material container 33. A carrier gas line 34 is inserted into the film forming material container 33. Ar gas serving as a carrier gas is blown into the film forming material container 33 from a carrier gas supply source 35 through the line 34. The solid material S of W(CO)₆ present in the film forming material container 33 is heated by the heater 33a to be sublimated into W(CO)₆ gas. The W(CO)₆ gas is carried by the carrier gas and is supplied to the shower head 30 through the gas line 32 and then supplied to the processing chamber 21.

The line 34 is provided with a mass flow controller 36, and valves 37a and 37b located at the upstream and downstream sides thereof. Further, the line 32 is provided with a flowmeter 65 for measuring a flow rate based on the amount of W(CO)₆ gas, and valves 37c and 37d located at the upstream and downstream sides thereof.

The line 32 is connected to a preflow line 61 at the downstream side of the flowmeter 65. The preflow line 61 is connected to a gas exhaust pipe 44 to be described later and gas is exhausted via the preflow line 61 for a predetermined period of time to stably supply a source gas into the processing chamber 21. Further, the preflow line 61 is provided with a valve 62 on the immediately downstream side of the junction between the line 32 of W(CO)₆ gas and the preflow line 61.

Heaters (not shown) are provided around the lines 32, 34 and 61 such that the W(CO)₆ gas is controlled to have a temperature of, e.g., 20 to 100° C., preferably, 25 to 60° C., at which the W(CO)₆ gas is not solidified.

Further, the line 32 is connected to a purge gas line 38, the other end of which is connected to a purge gas supply source 39. The purge gas supply source 39 supplies a nonreactive gas, such as Ar gas, He gas or N₂ gas, or H₂ gas as a purge gas. The film forming gas remaining in the gas line 32 is exhausted and the processing chamber 21 is purged by the purge gas. Further, the purge gas line 38 is provided with a mass flow controller 40, and valves 41a and 41b located at the upstream and downstream sides thereof.

Further, pre-coating may be performed prior to formation of a W film. In this case, an Si film, a W film and an Si film are sequentially formed and a nitriding process is performed between formations of these films. For this, there are provided an Si-containing gas supply unit for supplying an Si-containing gas (e.g., SiH₄ gas) and a nitriding gas supply unit for supplying a nitriding gas (e.g., NH₃ gas).

A gas exhaust pipe 44 is connected to the side surface of the gas exhaust chamber 43. The gas exhaust pipe 44 is connected to a gas exhaust device 45 including a high speed vacuum pump. As the gas exhaust device 45 is operated, the gas in the processing chamber 21 is uniformly supplied into a space 43a of the gas exhaust chamber 43, and then discharged through the gas exhaust pipe 44, so that the pressure of the processing chamber 21 can be rapidly decreased to a predetermined vacuum level. In the film formation process, the inner pressure of the processing chamber 21 ranges, e.g., from 0.10 to 666.7 Pa.

At the sidewall of the processing chamber 21, there are provided a loading/unloading port 49, through which a wafer (W) is transferred between the film forming apparatus 100 and a transfer chamber (not shown) adjacent thereto, and a gate valve 50 for opening and closing the loading/unloading port 49.

The film forming apparatus 100 includes a process controller 90 having a microprocessor (computer). Respective components of the film forming apparatus 100, such as the mass flow controllers 36 and 40, the flowmeter 65, the valves 37a, 37b, 37c, 37d, 41a, 41b and 62 and the heater power supply 26, are connected to and controlled by the process controller 90.

A user interface 91, including a keyboard for inputting commands or a display for displaying an operation status of the film forming apparatus 100, is connected to the process controller 90 to allow an operator to manage the respective components of the film forming apparatus 100.

Further, the process controller 90 is connected to a storage unit 92 which stores control programs for implementing various processes in the film forming apparatus 100 under control of the process controller 90, a control program, i.e., recipe, for performing a predetermined process in each component of the film forming apparatus 100 under process conditions, various databases, or the like. The recipe is stored in a storage medium of the storage unit 92. The storage medium may be a fixed storage medium such as a hard disk, or a portable storage medium such as a CD-ROM, a DVD or a flash memory. Further, the recipe may properly be transmitted from another apparatus via, e.g., a dedicated line.

If necessary, as a certain recipe is retrieved from the storage unit 92 in accordance with an instruction inputted through the user interface 91 and transmitted to the process controller 90, a desired process is performed in the film forming apparatus 100 under control of the process controller 90.

Next, the edge covering 24 will be described in detail.

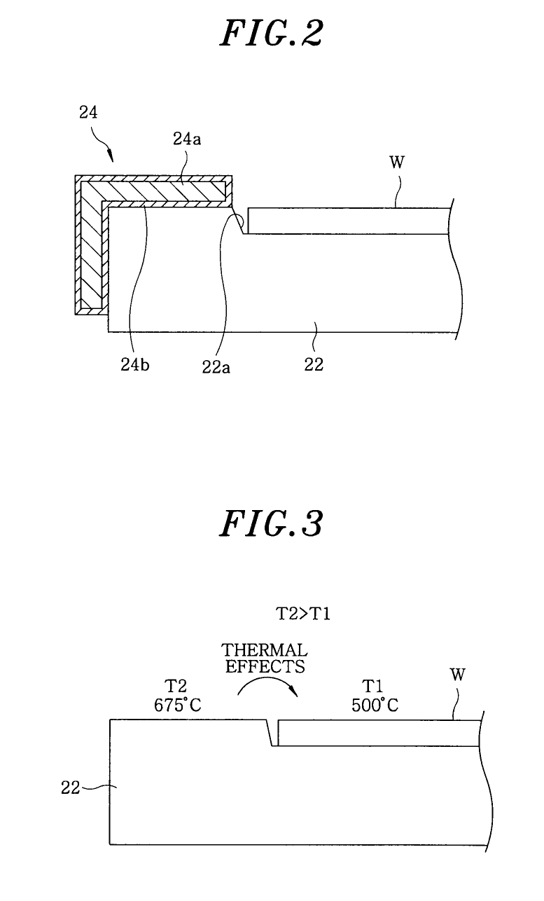

FIG. 2 is an enlarged cross sectional view illustrating the edge covering provided on the stage 22. The edge covering 24 functions to reduce thermal effects from the stage 22 to the peripheral portion of the wafer W. In order to exert such a function, at least an interface portion between the edge covering 24 and the stage 22 is made of a material whose emissivity is lower than that of a material of the stage 22.

In an example of FIG. 2, the edge covering 24 is configured as an inverted L-shaped annular member including a horizontal portion parallel to a mounting surface of the stage 22 and a vertical portion in contact with a side portion of the stage 22. Further, the edge covering 24 includes a basic member 24a and a low emissivity film 24b provided thereon. The low emissivity film 24b may be formed by a method such as CVD or PVD. Specifically, the basic member 24a is made of, e.g., silicon, and the low emissivity film 24b is made of, e.g., tungsten (W).

When the low emissivity film 24b is formed of a W film having substantially low emissivity, it is possible to inhibit a temperature increase in the peripheral region of the stage 22 that surrounds the wafer W mounted on the stage 22 due to the heat emitted from the stage 22. That is, at least an interface portion between the edge covering 24 and the stage 22 is made of a W film having low emissivity. Thus, it is possible to prevent an increase in the temperature of the edge covering 24 by reducing energy (an amount of heat) transferred from the stage 22 to the edge covering 24. Accordingly, the temperature increase in the peripheral region of the stage 22 that surrounds the wafer W mounted on the stage 22 is inhibited.

The edge covering 24 may have another structure without being limited to the above-described structure as long as it can reduce the temperature increase in the peripheral region of the stage 22 that surrounds the wafer W mounted on the stage 22. For example, the edge covering 24 may be made of only tungsten (W).

Preferably, the edge covering 24 has a thickness of 1 to 3 mm. When the thickness of the edge covering 24 is smaller than 1 mm, the temperature of the edge covering 24 increases due to its small thickness, thereby causing an increase in film thickness at a peripheral portion of the wafer and deterioration in in-plane uniformity of film thickness. Meanwhile, when the thickness of the edge covering 24 exceeds 3 mm, the film thickness may decrease at the peripheral portion of the wafer, and the in-plane uniformity of film thickness may be deteriorated, as can be seen from FIG. 9.

In a case where a W film is formed on the wafer W by using the film forming apparatus having the aforementioned configuration, if necessary, pre-coating may be performed prior to the film formation of the wafer W. The pre-coating is carried out under predetermined conditions by supplying an Si-containing gas such as SiH₄ gas from an Si-containing gas supply unit (not shown) to form an Si film in a processing chamber 21, supplying a nitriding gas such as NH₃ from a nitriding gas supply unit (not shown) to perform a nitriding process, supplying a W(CO)₆ gas to form a W film, performing a nitriding process, and forming an Si film. Then, a W(CO)₆ gas is supplied while a dummy wafer is mounted on the stage 22 to form a W film on an area of the stage 22 on which the wafer W is not mounted and on the surface of the edge covering 24.

After performing the pre-coating, if needed, as described above, then, formation of the W film is performed.

First, the gate valve 50 is opened, and a wafer W is loaded into the processing chamber 21 through the loading/unloading port 49 and is then mounted on the stage 22. Then, the stage 22 is heated by the heater 25, thereby heating the wafer W. Also, the processing chamber 21 is evacuated by using the vacuum pump of the gas exhaust device 45 such that the inner pressure of the processing chamber 21 is 6.7 Pa or less.

Next, the valves 37a and 37b are opened, and a carrier gas, e.g., Ar gas is blown into the film forming material container 33 containing a solid material S of W(CO)₆ from the carrier gas supply source 35. The material S of W(CO)₆ is heated by the heater 33a to be sublimated into W(CO)₆ gas. Subsequently, the valve 37c is opened and the produced W(CO)₆ gas is carried by a carrier gas. Then, the valve 62 is opened, and preflow is performed for a predetermined period of time such that the W(CO)₆ gas is discharged through the preflow line 61 to stabilize the flow rate of the W(CO)₆ gas.

Next, the valve 62 is closed, and the valve 37d is opened to introduce the W(CO)₆ gas into the line 32, thereby supplying the gas to the diffusion area 30d of the shower head 30 through the gas inlet port 30c. Then, the W(CO)₆ gas supplied into the diffusion area 30d is diffused and uniformly supplied toward the surface of the wafer W in the processing chamber 21 through the gas discharge holes 30b of the shower plate 30a. Accordingly, tungsten (W) produced by thermal decomposition of W(CO)₆ on the surface of the heated wafer W is deposited thereon to form a W film.

The inner pressure of the processing chamber 21 ranges from 0.10 to 666.7 Pa, as described above. If the pressure is higher than 666.7 Pa, the quality of the W film may be deteriorated, and if the pressure is lower than 0.10 Pa, a film forming rate becomes excessively low. Further, the residence time of W(CO)₆ gas is preferably 100 seconds or less. The flow rate of W(CO)₆ gas preferably ranges from 0.01 to 5 L/min.

When the W film having a predetermined thickness is formed, the valves 37a to 37d are closed to stop the supply of the W(CO)₆ gas, a purge gas is introduced from the purge gas supply source 39 to the processing chamber 21 to purge the W(CO)₆ gas. Then, the gate valve 50 is opened, and the wafer W is unloaded through the loading/unloading port 49.

In the film formation process, the temperature of the wafer W is controlled to have, e.g., 500° C. In order to maintain the temperature of the wafer W at 500° C., the stage 22 should be heated to 675° C. In this case, when the stage 22 has a larger diameter than that of the wafer W and the wafer W is mounted on the stage 22 without an edge covering, the stage 22 having a temperature T2 of 675° C. is adjacent to the peripheral portion of the wafer W having a temperature T1 of 500° C., as shown in a schematic diagram of FIG. 3. There is a large temperature difference of 175° C. between the wafer W and the stage 22. Accordingly, intermediates such as W(CO)₅ generated by the decomposition of the source gas of W(CO)₆ are more abundant on the stage 22 than on the wafer W. The intermediates generated on the peripheral region of the stage 22 exert a great influence on film formation in the peripheral portion of the wafer W. The more the intermediates are generated, the thicker the film is formed at the peripheral portion of the wafer W, thereby causing nonunifomity of film thickness.

In particular, decomposition of W(CO)₆ gas is initiated at a temperature of 100° C. and becomes severe at a temperature of 150° C. or more under normal pressure. That is, the W(CO)₆ gas is sensitive to temperature. When a film is formed by using a W(CO)₆ gas, the W(CO)₆ gas may be readily affected by radiant heat of the stage 22 due to low inner pressure of the processing chamber 21. Accordingly, this behavior becomes significant.

In this embodiment, the edge covering 24 is provided to cover a peripheral portion of the stage 22 at the outside of the wafer W in order to reduce thermal effects from the stage 22 to the peripheral portion of the wafer W. Accordingly, it is possible to prevent an increase in temperature of the peripheral region of the stage 22 that surrounds the wafer W mounted on the stage 22. Specifically, at least an interface portion between the edge covering 24 and the stage 22 is made of a material whose emissivity is lower than that of a material of the stage 22. Accordingly, it is possible to prevent an increase in the temperature of the edge covering 24 by reducing energy (an amount of heat) transferred from the stage 22 to the edge covering 24. Thus, the peripheral region of the stage 22 that surrounds the wafer W mounted on the stage 22 can be maintained at a temperature similar to the temperature of the wafer W. As a result, although a material used for CVD is an organic metal material such as W(CO)₆ which is decomposed at a temperature of 150° C. or less, the afore-mentioned problem may hardly occur.

In this case, emissivity of the interface portion between the edge covering 24 and the stage 22 is preferably 0.38 or less. Further, a temperature difference between the edge covering 24 and the wafer W is preferably 90° C. or less. More preferably, the emissivity is 0.23 or less and the temperature difference is 50° C. or less. In order to provide such a temperature difference, factors such as a material and shape of the edge covering 24 are appropriately determined.

In particular, as described above, when the edge covering 24 is configured by forming the low emissivity film 24b on the surface of the basic member 24a, the low emissivity film is present at the interface portion between the edge covering 24 and the stage 22. Thus, the edge covering 24 can provide a function of reducing thermal effects regardless of a material of the basic member 24a.

Silicon may be used as the material of the basic member 24a. Further, the low emissivity film 24b is preferably a metal film having high reflectivity, e.g., W film. Also in this configuration, the interface portion (the low emissivity film 24b in this embodiment) between the edge covering 24 and the stage 22 preferably has an emissivity of 0.38 or less. Further, the temperature difference between the edge covering 24 and the wafer W is within 90° C. More preferably, the emissivity is 0.23 or less, and the temperature difference is 50° C. or less. The edge covering 24 may be made of only tungsten (W).

Further, the ceramic material, such as AlN, of the stage 22 has an emissivity of about 1 in high-energy infrared rays, whereas the W film used as the low emissivity film 24b has an emissivity of about 0.15. Thus, a great effect can be obtained as described above. However, the emissivity of silicon of the basic member ranges from about 0.30 to 0.72 and, particularly, ranges from 0.43 to 0.72 at a temperature of 400 to 680° C., which is lower than that of the ceramic material of the stage 22. Accordingly, a desirable effect can be obtained even though the edge covering 24 is made of only silicon.

Next, effects of the edge covering 24, depending on the structure thereof, are evaluated by simulation and the results thereof will be described.

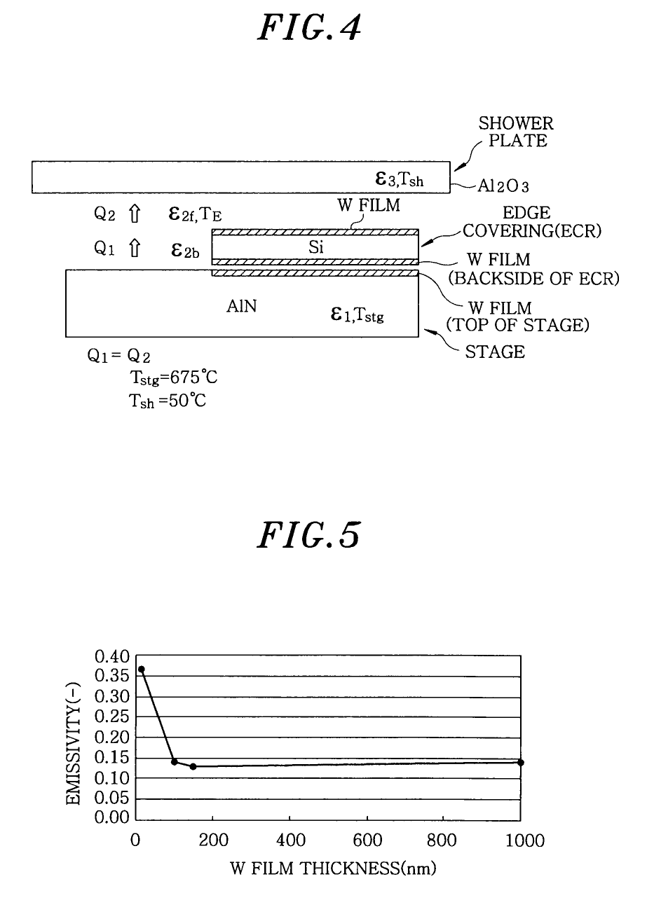

Herein, the temperature of the edge covering was obtained by calculating thermobalance by using a model shown in FIG. 4. The temperature T_{E} of the edge covering was calculated by using the Stefan-Boltzmann equation, under the conditions that a temperature T_{stg} of the stage is set to 675° C., a temperature Tₛₕ of the shower head is set to 50° C., Q1 is an amount of energy (amount of heat) radiated from the stage toward the wafer and the edge covering, Q2 is an amount of energy (amount of heat) radiated from the wafer and the edge covering toward the shower head, and Q1 is equivalent to Q2 (Q1=Q2). Further, the film formation pressure is low, i.e., about 20 Pa. Accordingly, gas heat transfer is negligible and radiant heat transfer was only considered.

Further, silicon (emissivity ε_{2f}: 0.65) with a thickness of 1 mm was used as the edge covering (ECR). The simulation was performed for the cases where no W film was formed between the edge covering and the stage and a W film (emissivity ε_{2b}=0.18) with a thickness of 500 nm was formed on any one or both of the backside surface of silicon and the surface of the stage (emissivity ε₁=0.85). The emissivity (ε3) of the shower head was 0.65.

Further, simulation and calculation were performed for the edge covering having a W film with a thickness of 500 nm formed on silicon. The results thus obtained are shown in Table 1 below.

TABLE 1

| | | No. 1 | No. 2 | No. 3 | No. 4 |
|---|---|---|---|---|---|
| W film | Backside | Absence | Absence | Presence | Presence |
| | of ECR | | | | |
| | Top of | Absence | Presence | Absence | Presence |
| | stage | | | | |

| | | | | |
|---|---|---|---|---|
| ECR temperature (° C.) | 618.9 | 526.8 | 532.7 | 473.5 |
| Temperature difference between stage and | 56.1 | 148.2 | 142.3 | 201.5 |
| ECR (° C.) | | | | |

As can be seen from Table 1, in the case (No. 1) where only silicon was used as the edge covering, the temperature of the edge covering was 618.9° C. and decreased by 56.1° C. from an initial temperature of 675° C. However, in the cases (No. 2 and 3) where a W film was formed on the backside surface of silicon or the top surface of the stage, the ECR temperature was decreased to about 530° C., which is close to the wafer temperature. In the case (No. 4) where a W film is formed on both the backside surface of the edge covering and the top surface of the stage, the ECR temperature was decreased to 473.5° C., which is lower than the wafer temperature.

Next, the measurement results of a relationship between film thickness and emissivity in the W film of the edge covering are described. FIG. 5 is a graph showing a relationship between W film thickness plotted on a horizontal axis and emissivity plotted on a vertical axis. As can be seen from FIG. 5, when the W film thickness is 100 nm or larger, a low emissivity of about 0.15 can be stably obtained. That is, it is preferable that the W film has a thickness equal to or larger than 100 nm to stably obtain low emissivity effects.

Next, a W film was formed on the wafer in the case (Test 1) of using an edge covering wherein a W film with a thickness of 500 nm was formed on the backside surface of a basic member made of silicon and having a thickness of 1 mm, the case (Test 2) of using an edge covering including only a basic member made of silicon without any W film, and the case (Test 3) where no edge covering was used.

After pre-coating was performed, the wafer was transferred and main film formation of a W film was carried out.

First, in the pre-coating, first Si film formation was performed at an initial temperature, i.e., 400° C., of the stage. Then, after the temperature of the stage was increased to 550° C., a first nitriding process was performed and a W film was formed. Subsequently, after the temperature of the stage was increased to 600° C., a second nitriding process was performed and second Si film formation was performed. Then, after the temperature of the stage was increased to 680° C., a third nitriding process was performed. Finally, W film formation was formed using a dummy wafer. The conditions were as follows.

Pre-coating conditions

<First Si film formation>

Temperature of Stage: 400° C.

Pressure: 326.6 Pa

Gas flow rate: Ar/SiH₄=600/100 mL/min(sccm)

Film formation time: 600 sec

<First nitriding process>

Temperature of Stage: 550° C.

Pressure: 133.3 Pa

Gas flow rate: Ar/NH₃=50/310 mL/min(sccm)

Process time: 60 sec

<First W film formation>

Temperature of Stage: 550° C.

Temperature of Container: 41° C.

Pressure: 6.7 Pa

Gas flow rate: carrier Ar/diluent Ar=40/320 mL/min(sccm)

Film formation time: 60 sec

<Second nitriding process>

Temperature of Stage: 600° C.

Pressure: 133.3 Pa

Gas flow rate: Ar/NH₃=50/310 mL/min(sccm)

Process time: 60 sec

<Second Si film formation>

Temperature of Stage: 600° C.

Pressure: 326.6 Pa

Gas flow rate: Ar/SiH₄=600/100 mL/min(sccm)

Film formation time: 1800 sec

<Third nitriding process>

Temperature of Stage: 680° C.

Pressure: 133.3 Pa

Gas flow rate: Ar/NH₃=50/310 mL/min(sccm)

Process time: 60 sec

<Second W film formation>
This process was carried out while a dummy wafer was mounted on the stage.

Temperature of Stage: 680° C.

Temperature of Container: 41° C.

Pressure: 20 Pa

Gas flow rate: carrier Ar/diluent Ar=90/700 mL/min(sccm)

Film formation time: 300 sec

After the pre-coating, main film formation of a W film was performed. The film formation conditions are as follows.
Main film formation conditions of W film

Temperature of Stage: 675° C.

Temperature of Container: 41° C.

Pressure: 20 Pa

Gas flow rate: carrier Ar/diluent Ar=90/700 mL/min(sccm)

Film formation time: 48 sec

Film thickness: 10 nm (set)

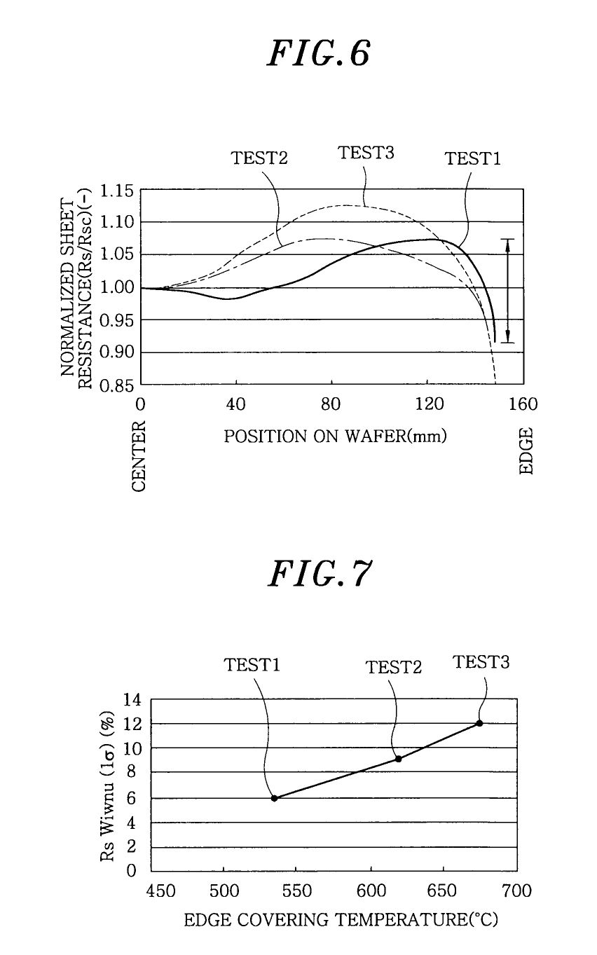

In Tests 1 to 3, sheet resistance (Rs) of the W film formed on the wafer W was measured and the measurement results are shown in FIG. 6. FIG. 6 is a graph showing in-plane distribution of sheet resistance, wherein a horizontal axis represents a position on the wafer from the center toward the edge and a vertical axis represents sheet resistance of a W film. In FIG. 6, the vertical axis represents sheet resistance (Rs) normalized by the center sheet resistance (Rsc). Further, in-plane uniformity (WiWNU) of sheet resistance at 1σ was 5.9% in Test 1, 9.1% in Test 2 and 12.0% in Test 3. As the thickness of the W film increases, the sheet resistance decreases. Accordingly, in-plane distribution of the sheet resistance is an index of in-plane distribution of film thickness and in-plane distribution of temperature. It was confirmed that the film thickness uniformity was improved by providing the edge covering (in particular, the edge covering having a W film on its backside surface). It is because an increase in film thickness is prevented at the peripheral portion of the wafer, as shown in FIG. 6.

The temperature of the edge covering was 530° C. in Test 1 and 620° C. in Test 2. In Test 3 wherein no edge covering is provided, the temperature of the edge covering was assumed to be 675° C. (the temperature of the stage). Under these temperature conditions, a relationship between the edge covering temperature and in-plane uniformity of sheet resistance (Rs) was evaluated and the results thereof are shown in FIG. 7. FIG. 7 is a graph showing a relationship between edge covering temperature plotted on a horizontal axis and in-plane uniformity of sheet resistance plotted on a vertical axis. In-plane uniformity (WiWNU) of sheet resistance should be 8% or less at 1σ under general process conditions. However, the temperature of the edge covering should be 590° C. or lower to obtain in-plane uniformity (8% or less), as can be seen from FIG. 7. At this time, since the wafer temperature is 500° C., it is necessary that the temperature difference between the edge covering 24 and the wafer W serving as a target substrate is adjusted to be within 90° C.

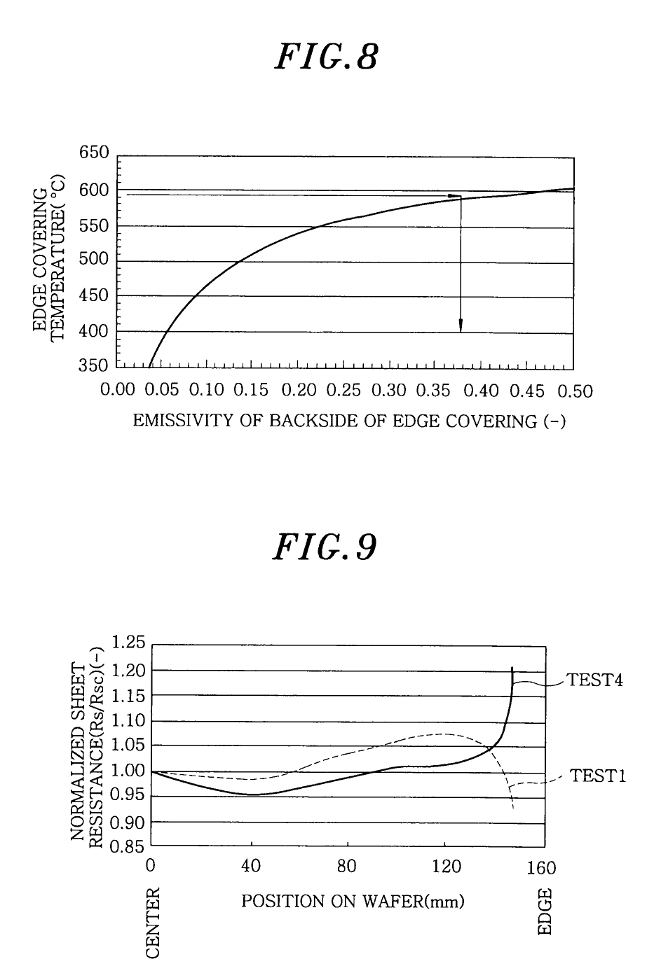

An investigation was conducted on emissivity required to adjust the temperature of the edge covering to be 590° C. or less in order to realize desired in-plane uniformity. A relationship between the temperature of the edge covering and emissivity of the backside surface of the edge covering was evaluated by using the afore-mentioned thermobalance model and results thus obtained are shown in FIG. 8. FIG. 8 is a graph showing a relationship between emissivity of the backside surface of the edge covering plotted on a horizontal axis and the temperature of the edge covering plotted on a vertical axis. As can be seen from FIG. 8, when emissivity of the backside surface of the edge covering is 0.38 or less, the temperature of the edge covering can be adjusted to be 590° C. or less, thereby obtaining desired uniformity.

Next, the effect of the thickness of the edge covering was examined. In the afore-mentioned Test 1, W film formation was carried out by using an edge covering including a silicon basic member with a thickness of 1 mm and a W film with a thickness of 500 nm formed on the basic member. In this case, a film formation test was performed by using an edge covering including a silicon basic member with a thickness of 3 mm and a W film with a thickness of 500 nm formed on the basic member (Test 4). Film formation conditions were the same as in Tests 1 to 3. The sheet resistance (Rs) of the W film was measured and in-plane uniformity (WiWNU) at 10 was 6.5%. Further, in-plane distribution of the sheet resistance is shown in FIG. 9. FIG. 9 is a graph showing a relationship between a position on the wafer from the center toward the edge, which is plotted on a horizontal axis, and sheet resistance plotted on a vertical axis. In-plane distribution of Test 1 is also shown in FIG. 9.

As shown in FIG. 9, sheet resistance (Rs) in the peripheral portion of the wafer is varied depending on the thickness of the edge covering. When the thickness of the silicon basic member is increased to be 3 mm, the sheet resistance (Rs) in the peripheral portion of the wafer is increased on the contrary. The reason is as follows. The temperature of the surface of the edge covering facing the shower head is lower than that of the surface of the edge covering in contact with the stage. Accordingly, temperature distribution occurs in a thickness direction of the edge covering, and this temperature distribution increases as the thickness of the edge covering increases.

As can be seen from these results, variation of sheet resistance (Rs), i.e., film thickness, at the peripheral portion of the wafer can be controlled by controlling the thickness of the edge covering. Thus, it is possible to obtain more uniform sheet resistance distribution (film thickness distribution).

The present invention may be variously modified without being limited to the above-described embodiment.

For example, although an edge covering including a silicon basic member and a W film formed thereon is used in the above-described embodiment, the present invention is not limited thereto. That is, the present invention may be applied under conditions similar to the aforementioned conditions by using a basic member made of, e.g., Al₂O₃, AlN, SiO₂ and SiC having an emissivity relatively close to that of Si and to other films, such as TaN, Ta, TiN and Ti films, having an emissivity relatively close to that of a tungsten (W) film. Further, various materials may be used in combinations. Furthermore, although an edge covering including a silicon basic member and a W film formed thereon is described in the above-described embodiment, a film may be formed on the stage. Moreover, the edge covering is not limited to the structure including a basic member and a film, and may have a single structure.

Although a film forming apparatus for forming a W film by using chemical vapor deposition (CVD) is exemplified in the above-described embodiment, any apparatus for forming a film via CVD may be used without particular limitation.

Although W(CO)₆, that is, an organic metal material which is decomposed at a temperature of 150° C. or less is used as a CVD material in the afore-mentioned embodiment, other organic metal materials, Ti[N(CH₃)₂]₄, Ru₃(CO)₁₂, Ta[N(C₂H₅)₂]₃[NC(CH₃)₃], Ta[NC(CH₃)₂C₂H₅][N(CH₃)₂]₃ or (hfac)Cu(tmvs) may be used in case of forming a Ti, Ru, Ta or Cu film. Further, although a semiconductor wafer is used as a target substrate in the above-described embodiment, other substrates including a substrate for flat panel display (FPD), which is a representative example of a liquid crystal display (LCD), may be used without particular limitation.

While the invention has been shown and described with respect to the embodiments, it will be understood by those skilled in the art that various changes and modification may be made without departing from the scope of the invention as defined in the following claims.

What is claimed is:

1. A CVD film forming apparatus for forming a predetermined film on a target substrate via CVD by reacting a film forming gas on a surface of the substrate while heating the substrate, the apparatus comprising:
a processing chamber capable of being maintained at vacuum;
a stage for mounting thereon the substrate in the processing chamber, the stage having a diameter larger than that of the substrate;
a heating device provided in the stage to heat the substrate;
a gas supply unit for supplying the film forming gas into the processing chamber;
a gas exhaust device for exhausting the processing chamber to vacuum; and
a covering for covering a peripheral region of the stage that surrounds the substrate mounted on the stage to reduce thermal effects from the stage to a peripheral portion of the substrate.

2. The apparatus of claim 1, wherein a surface of the covering in contact with the stage has an emissivity lower than an emissivity of the stage.

3. The apparatus of claim 2, wherein the stage is made of ceramic, and the surface of the covering in contact with the stage has an emissivity of 0.38 or less.

4. The apparatus of claim 3, wherein at least a part of the covering including the surface in contact with the stage is made of tungsten.

5. The apparatus of claim 4, wherein the covering is made of only tungsten.

6. The apparatus of claim 1, wherein a material and shape of the covering are determined such that a temperature difference between the covering and the substrate is adjusted to 90° C. or less when the substrate is heated by the heating device.

7. The apparatus of claim 1, wherein the covering has a ring shape to surround the peripheral portion of the substrate.

8. The apparatus of claim 1, wherein the covering has a thickness of 1 mm to 3 mm.

9. The apparatus of claim 1, wherein the gas supply unit supplies the film forming gas by using a metal material which is decomposed at a temperature of 150° C. or less.

10. A CVD film forming apparatus for forming a predetermined film on a target substrate via CVD by reacting a film forming gas on a surface of the substrate while heating the substrate, the apparatus comprising:
a stage for mounting thereon the substrate in a processing chamber, the stage having a diameter larger than that of the substrate;
a heating device provided in the stage to heat the substrate;
a gas supply unit for supplying the film forming gas into the processing chamber;
a gas exhaust device for exhausting the processing chamber to vacuum; and
a covering for covering a peripheral region of the stage that surrounds the substrate mounted on the stage, the covering including a basic member and a low emissivity film formed on at least a backside surface of the basic member.

11. The apparatus of claim 10, wherein the stage is made of ceramic and the low emissivity film of the covering has an emissivity of 0.38 or less.

12. The apparatus of claim 10, wherein the basic member is made of silicon and the low emissivity film is made of tungsten.

13. The apparatus of claim 10, wherein the low emissivity film has a thickness of 100 nm or more.

14. The apparatus of claim 10, wherein a material and shape of the basic member and the low emissivity film of the covering are determined such that a temperature difference between the covering and the substrate is adjusted to 90° C. or less when the substrate is heated by the heating device.

15. The apparatus of claim 10, wherein the covering has a ring shape to surround a peripheral portion of the substrate.

16. The apparatus of claim 10, wherein the covering has a thickness of 1 mm to 3 mm.

17. The apparatus of claim 10, wherein the gas supply unit supplies the film forming gas by using a metal material which is decomposed at a temperature of 150° C. or less.
